(19) United States
(12) Patent Application Publication
(10) Pub. No.: US 2026/0059905 A1
(43) Pub. Date: Feb. 26, 2026

(54) OPTICAL EMITTER STRUCTURES WITH INTEGRATED DISTRIBUTED BRAGG REFLECTORS

(71) Applicant: ADEIA SEMICONDUCTOR BONDING TECHNOLOGIES INC., San Jose, CA (US)

(72) Inventors: Oliver Zhao, Sunnyvale, CA (US); Rajesh Katkar, Milpitas, CA (US); Yan Chai, Fremont, CA (US)

(21) Appl. No.: 18/900,290

(22) Filed: Sep. 27, 2024

Related U.S. Application Data
(60) Provisional application No. 63/685,967, filed on Aug. 22, 2024.

(51) Int. Cl. H01L 33/46; H01L 25/16

(52) U.S. Cl. CPC H10H 20/841; H01L 25/167; H10H 20/034

(57) ABSTRACT

Optoelectronic light emitting devices are provided with directly bonded circuitry, such as control or driver circuitry. The optoelectronic light emitting devices incorporate distributed Bragg reflector (DBR) layers that can be tuned to reflect the light of a particular wavelength, and that facilitate direct bonding and electrical contact between optoelectronic light emitting device substrates (wafers or dies) and control circuitry. In some embodiments the DBR layers provide direct bonding interfaces, such as hybrid bonding surfaces.

### BACKGROUND

### Field

The field relates to microelectronic assemblies including illumination sources and circuitry, such as semiconductor devices.

### Description of the Related Art

The development of optoelectronic illumination sources, such as microLED technologies, is evolving and higher performance devices are sought. For example, current fabrication of microLEDs can be slow and time consuming, and utilize high-temperature techniques to package with other circuits, which may thermally stress various components within certain microLED products. Further, the resulting microLEDs can face light loss during operation as light is emitted omnidirectionally from a microLED and any light not directed towards the desired optical pathway contributes to a decreased brightness of the microLED. This light emission inefficiency is in part related to the architecture of current microLEDs.

Accordingly, a more efficient fabrication process and an improved optoelectronic illumination source, such as a microLED structure, that mitigates this light loss is needed.

### BRIEF DESCRIPTION OF THE DRAWINGS

Features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIGS. 1A-1B are schematic cross sections illustrating direct bonding, particularly hybrid bonding, of microelectronic elements.

FIGS. 2A-2G are schematic cross sections illustrating a process of forming an optical emitter structure with distributed Bragg reflector (DBR) layers and hybrid bonded circuitry, according to one embodiment.

FIGS. 3A-3F are schematic cross sections illustrating a process of forming an optical emitter structure having an array of optical emitters, a DBR structure and hybrid bonded circuitry, according to one embodiment.

FIGS. 4A-4C are schematic cross sections illustrating a process of forming a microLED structure having a DBR structure and directly bonded circuitry, according to one embodiment.

FIGS. 5A-5C are schematic cross sections illustrating a process of forming a microLED array structure having DBR structures and directly bonded circuitry, according to one embodiment.

FIGS. 6A-6F are schematic cross sections illustrating a process of forming a microLED array structure having a DBR layer and hybrid bonded circuitry, according to one embodiment.

FIGS. 7A-7C are schematic cross sections illustrating different configurations of a microLED structure having hybrid bonding interfaces at various locations, according to embodiments.

FIGS. 8A-8F are schematic cross sections illustrating a microLED array structure having conformal DBR layers and hybrid bonded circuitry, according to one embodiment.

FIGS. 9A-9F are schematic cross sections illustrating a microLED array structure having conformal DBR layers and hybrid bonded circuitry, according to one embodiment.

FIG. 10 is a schematic cross section illustrating a laser diode structure having at least one distributed Bragg reflector implemented as a direct bonding layer, according to one embodiment.

Like reference numbers are used to describe like features throughout the description and drawings.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and include other uses of the inventions and obvious modifications and equivalents thereof. Embodiments of the inventions are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments of the inventions can comprise several novel features and no single feature is solely responsible for its desirable attributes or is essential to practicing the inventions herein described.

When fabricating microelectronic illumination devices, such as micro light emitting diodes (microLEDs), light emitted from the device can be transmitted from all directions. To help ensure that the light emitted is directed to the desired light path, a reflective material can be added to a surface of the device, which can reflect the light emitted in different directions back into the desired light path, which can increase brightness. Traditionally, metals may be used as the reflective material. However, metals tend to have wavelength-dependent reflectance (i.e., the metals may have varying amounts of reflectance for different wavelengths of light). For example, most metals are not very reflective of blue light (e.g., at a wavelength of 482 nm, gold (Au) may have a reflectance of between 40% and 50% and copper (Cu) may have a reflectance of between 50% and 60%). Metal reflectors can also make electrical connection of device electrodes more challenging.

In addition to the wavelength dependent reflectance of some metals, the fabrication process of optical emitters like microLEDs today include an approach that uses a high temperature (e.g., 280-350° C.) AuSn eutectic reflow process, where the eutectic layer is added on the back side of the chip(s) or bonding frame/wafer. This process can be slow and time consuming. Further, because of the high temperatures used, it could also prove detrimental to structures that are sensitive to high temperatures (e.g., sensors that might be included in microLED displays).

DBRs, also referred to as DBR structures or DBR layers, can be used to reflect the light produced by the microLEDs. DBRs are structures formed from multiple, alternating thin film layers of materials having relatively large and small refractive indices to reflect light of specific wavelengths, and DBRs can be designed to enable a reflectance of more than 99.5% of a selected wavelength of light. As such, the implementation of DBRs in the fabrication of coherent illumination sources, such as microLEDs and laser diodes, can be useful for enhancing the luminosity, such as for pixels in a device (e.g., a microLED display). Further, and as described herein, the DBRs can be more readily integrated into an optoelectronic device and because they are typically insulating rather than conducting, can also be used as a bonding layer within the microLEDs for a direct bonding (including hybrid bonding) process, eliminating the AuSn eutectic bonding process. Alternating layers can comprise two or more dielectric layers, such as ceramic materials. For example, a typical DBR can include between 2 pairs and 20 pairs, between 2 pairs and 6 pairs, or between 8 pairs and 16 pairs of alternated dielectric layers. Non-limiting examples include SiO₂, TiO₂, GaN, ZrO₂, SiN, Al₂O₃, etc. The DBR as a bonding layer can be formed to include electrical contacts, which can help to provide electrical connection within the optoelectronic emitting device, and the DBR can enhance light extraction performance. Additionally, the DBR can be fabricated based on the wavelength of light to be emitted, so as the DBR can be optimized to maximize light reflection for coherent light sources, such as laser diodes or microLEDs.

The DBR as a bonding layer can be implemented in a variety of applications. For example, the DBR as a bonding layer can be used to fabricate different types of emitters or light or illumination sources, including microLEDs, as exemplified in the embodiments, or other illumination sources such as lasers, laser diodes (e.g., vertical cavity surface emitting lasers, VCSELs) for co-packaged optics (CPO) applications, etc. Optical integrated devices and electronic integrated devices can be integrated using techniques taught herein, including one or more DBR structures as a bonding layer. In one example, displays, such as microLED displays, can include these emitters formed using the DBR as a bonding layer. In another example, a laser (e.g., laser diode) can be directly bonded to active circuitry, a waveguide, or directly bonded to an interposer, which, in turn, can also be bonded to a processor, switches, memory module, and/or photonic integrated circuit (PIC)/electronic integrated circuit (EIC) module. High-performance displays maximizing light extraction can benefit from the integration of the DBRs as described herein. Additionally, future microLED displays that may embed sensors within the displays (e.g., smart displays for AR/VR, automotive, medical/biotechnology displays, etc.) may benefit from a microLED fabrication process that can use low or room temperature bonding techniques (described herein), as compared to the conventional high temperature eutectic bonding processes currently used in microLED fabrication.

### Examples of Direct Bonding Methods and Directly Bonded Structures

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

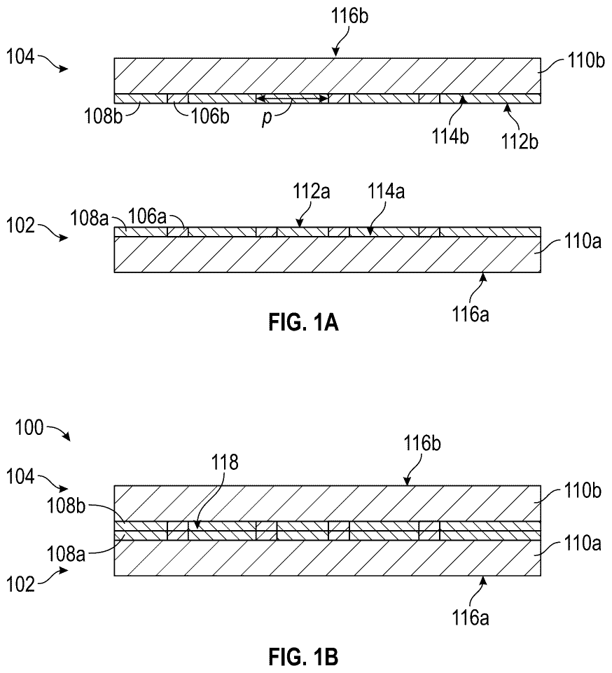

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/°C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

### Examples of Optical Emitters With Distributed Bragg Reflector Bonding Layers

Various embodiments disclosed herein relate to light or illumination sources, or optical emitters, having a DBR. In particular, the DBR as a bonding layer for the optical emitters, such as microLEDs and laser diodes (e.g., vertical-cavity surface-emitting laser, VCSEL), is described. As described herein, an optoelectronic or optical emitter assembly (e.g., a microLED assembly or a laser diode assembly) can include one or more optoelectronic light emitting device(s) (e.g., microLED device or array, or a laser diode device) and a circuitry element with or without active devices (e.g., a complementary metal oxide semiconductor (CMOS) driver, a thin-film transistor (TFT) backplane, a waveguide, or an interposer). The optoelectronic light emitting device can include an illumination source (e.g., a plurality of semiconductor layers including an active region) and at least one electrode. Example optoelectronic assemblies include bonded structures, such as a PIC bonded to an EIC, or a PIC bonded to an interposer.

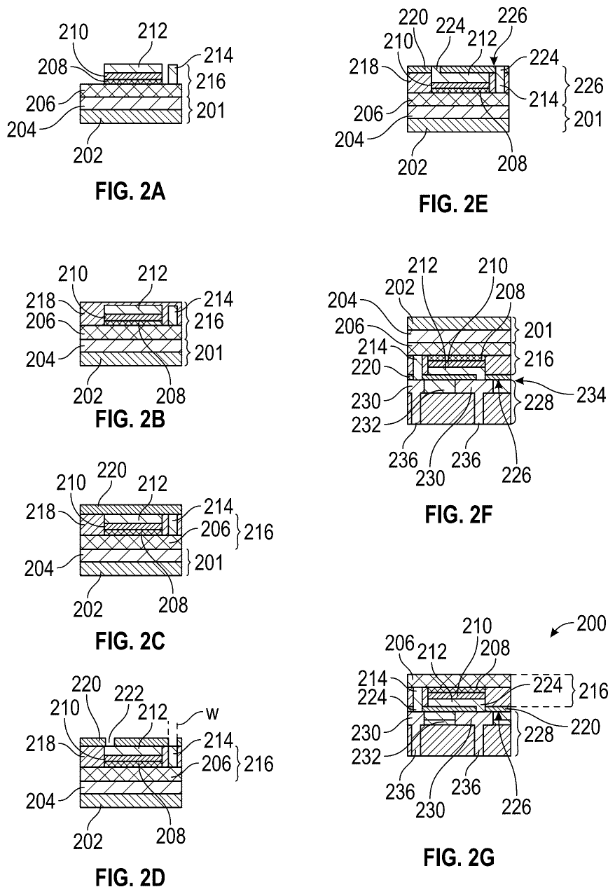

FIGS. 2A-2G illustrate a process for fabricating an optoelectronic assembly (e.g., a microLED assembly 200 in FIG. 2G). As described herein, a microLED assembly 200 can include a microLED device 216 and a circuitry element 228 (e.g., a CMOS driver or a TFT backplane). To form the microLED assembly 200, a substrate 202 (e.g., sapphire, silicon, aluminum nitride, etc.) is provided and a buffer layer 204 (e.g., GaN, GaAs, GaP, InP, InGaN, AlGaN, AlGaInP, etc.) is disposed on the substrate 202. Together, the substrate 202 and the buffer layer 204 can be referred to as a carrier member 201. A semiconductor layer of a first type (e.g., an n-type semiconductor 206) is disposed over the buffer layer 204. For example, the n-type semiconductor 206 can be n-GaN. After formation of the n-type semiconductor 206 layer, the remaining layers making up the microLED (or LED) can be formed. In the illustrated embodiment, the LED comprises an active region 208, such as a multiple quantum well (MQW), and another semiconductor layer of a second type (e.g., a p-type semiconductor 210) can be formed over the n-type semiconductor 206. The illumination source of the illustrated embodiment includes the semiconductor layers (e.g., n-type semiconductor 206 and p-type semiconductor 210) and the intervening active region 208. In some cases, the illumination source is formed through epitaxial growth of each of the layers over the carrier member 201. Although FIGS. 2A-2G illustrate the semiconductor layers of the first and second types as being the n-type semiconductor 206 and the p-type semiconductor 210, in some cases, the semiconductor layer of the first type can be a p-type semiconductor and the semiconductor layer of the second type can be an n-type semiconductor.

To operate as a microLED and emit light, the microLED device 216 can include electrodes to provide electrical connection to the relevant semiconductor layers. For example, a first electrode 212 can be formed or deposited over the p-type semiconductor 210 and a second electrode 214 can be formed or deposited over the n-type semiconductor 206 as shown in FIG. 2A. The first and second electrodes 212, 214, which can also be referred to as p-type and n-type contacts due to the semiconductor layers with which they make contact, can advantageously comprise transparent conductive material, such as but not limited to indium tin oxide (ITO).

Referring to FIG. 2B, after formation of the microLED device 216 in FIG. 2A, a dielectric 218 can be formed over the microLED device 216. The dielectric 218 can comprise an inorganic dielectric, such as silicon oxide, silicon nitride, or silicon oxynitride. In some embodiments, the dielectric 218 is an optically transparent material (e.g., can transmit light having a wavelength in the visible light range, the infrared light range, etc.). The dielectric 218 can then be thinned or planarized until the dielectric 218 is coplanar with the electrodes 212, 214 of the microLED device 216. In some embodiments, epitaxially grown layers (e.g., p-type semiconductor 210 and active region 208 or MQWs,) are patterned to expose layer 206 and one or more layers of dielectric 218 can be deposited; which is followed by processing (e.g., polishing) and patterning (e.g., forming vias in) the dielectric 218 further to deposit electrodes 214 and 212.

As shown in FIG. 2C, a distributed Bragg reflector (DBR 220) is formed over the thinned dielectric 218. The DBR 220 is formed from multiple, alternating thin film layers of materials having relatively large and small refractive indices to reflect light of a particular wavelength. Examples of materials that can be used in the DBR 220 include SiO₂, TiO₂, GaN, ZrO₂, SiN, etc. For example, in some embodiments, the DBR 220 can include alternating layers of SiO₂ and TiO₂. The thickness of the DBR 220 can be selected based on the wavelengths of light to be emitted by the microLED. For example, individual layers (not shown) in the DBR 220 can have a thickness that is approximately one fourth the wavelength of the light to be reflected, or multiples of quarter-wavelength thicknesses. The DBR 220 can be fabricated to be optimized for reflecting one or more specific wavelengths of light as needed.

Referring to FIG. 2D, the DBR 220 can be patterned to form openings 222. For example, a blanket DBR 220 as shown in FIG. 2C can be patterned by masking and etching. These openings 222 can be located over a portion of the first electrode 212 and over the second electrode 214.

As shown in FIG. 2E, the openings 222 can be filled with an electrically conductive material to form contacts 224. In some embodiments, the contacts 224 can be formed using the same material as that of the first electrode 212 and/or the second electrode 214. In some embodiments, particularly where the contacts 224 are small compared to the emitting surface, the contacts 224 can be formed from a metal, such as copper. In some embodiments, the openings 222 can have a width in a range between approximately 0.5 μm and 50 μm, such as about 0.5 μm to 3 μm, or about 1 μm to 10 μm, or about 5 μm to 50 μm. For embodiments in which the material of the contacts 224 are opaque or reflective (such as copper), minimizing the size of the openings 222 within the reflective DBR 220 enables most of the reflection to be accomplished by the DBR 220, which can be precisely tuned to maximize reflection of wavelengths of interest, whereas metal may not be optimized to reflect the wavelength of interest. For embodiments in which the material of the contacts 224 are transparent (such as ITO), minimizing the size of the openings 222 within the reflective DBR 220 can help reduce light loss by minimizing areas having low reflectivity, facing difficulties with reflecting the light back into the desired light propagation pathway. Having the DBR 220 cover most of the emitting surface of the illumination source is of particular interest for coherent light sources, such as diode emitters (LEDs or laser diodes). In some embodiments, a continuous portion of the DBR 220 can cover a majority of the surface area of the microLED device 216. For example, the DBR 220 can cover between approximately 50% and 99%, such as between approximately 90% and 99%, between approximately 75% and 98%, between approximately 50% and 95%, or between approximately 70% and 90% of the surface area of the microLED device 216. A surface 226 of the DBR 220 including the contacts 224 can be polished and prepared for direct bonding (as described herein), after which it can be referred to as a bonding surface, and more particularly, as a hybrid bonding surface.

Referring to FIG. 2F, once prepared, the structure can be flipped over and directly bonded (e.g., hybrid bonded) to a circuitry element 228 to form the microLED assembly 200. The circuitry element 228 can be an active device, such as a CMOS) or TFT backplane, or a passive device such as some waveguide and/or interposer structures. The circuitry element 228 may be an LED driver for controlling the current to be provided to the microLED device 216. The circuitry element 228 includes contacts 230 embedded in a dielectric 232. The contacts 230 and the dielectric 232 of the circuitry element 228 are coupled to the surface 226 of the DBR 220 through a direct bond at the bond interface 234. The contacts 230 can be connected to the circuitry 236 in the circuitry element 228, which can include wiring for passive circuit elements, and can additionally include active devices for active circuit elements.

FIG. 2G illustrates that after the direct bonding of the surface 226 to the circuitry element 228, the carrier member 201 can be removed, leaving the n-type semiconductor layer 206 as the upper layer of the formed microLED 216 and the microLED assembly 200. For example, the substrate 202 and the buffer layer 204 of the carrier member 201 can be removed by grinding, polishing, and/or laser ablation. In some embodiments, after the carrier member 201 has been removed, an optically transparent material (not shown) can be formed or disposed over the n-type semiconductor 206 as a cap layer. In some embodiments, this optically transparent material may be a glass substrate. In some embodiments, optical devices such as lenses can be integrated over the n-type semiconductor 206 or the overlying cap layer.

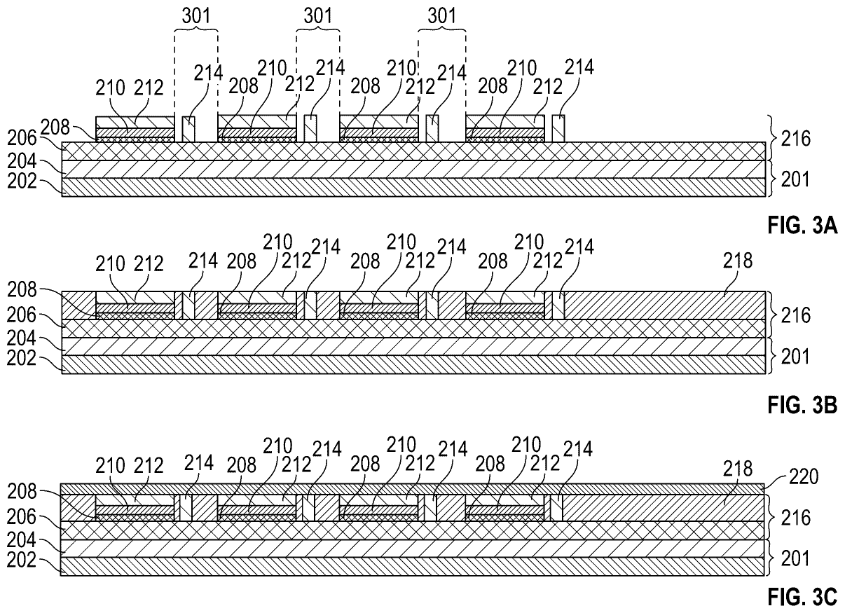

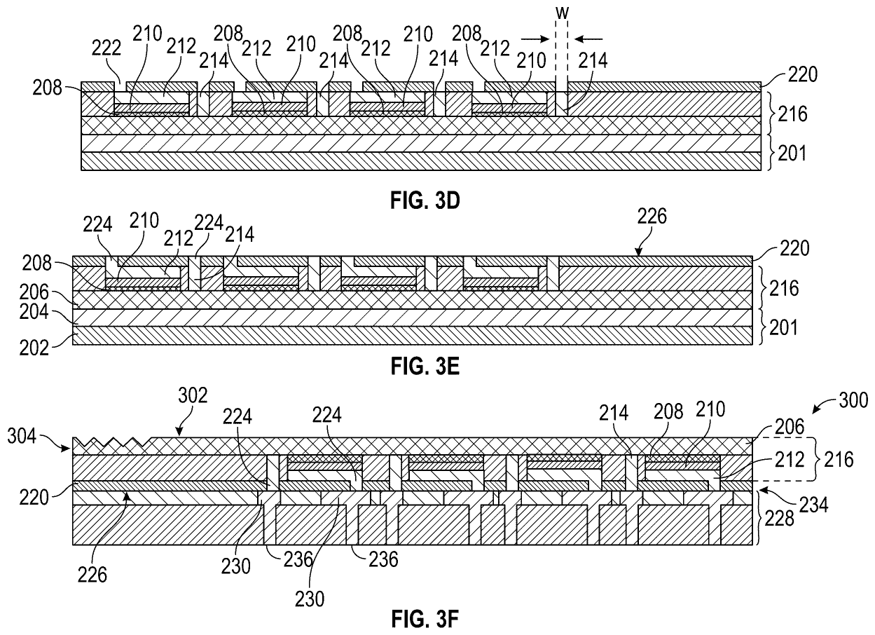

FIGS. 3A-3F illustrate a process for fabricating a microLED array assembly 300 having contact arrangements similar to flip-chip type assemblies, according to another embodiment. The process illustrated in FIGS. 3A-3F is similar to the process illustrated in FIGS. 2A-2G, except that in FIGS. 3A-3F, an array of light emitting devices (e.g., microLEDs) is formed. Unless otherwise noted, like reference numbers are employed to refer to the components of FIGS. 3A-3F that are the same as or generally similar to the components of FIGS. 2A-2G, and alternatives noted above with respect to FIGS. 2A-2G are likewise applicable to the embodiment of FIGS. 3A-3F. As shown in FIG. 3A, a plurality of microLEDs can be formed over the carrier member 201 through a process including deposition (e.g., epitaxial growth), patterning, and etching. For example, an n-type semiconductor 206 layer can be formed over the carrier member 201 that can be shared across an array of microLED devices 216, where an individual microLED device may be the same as that described in FIGS. 2A-2G. The entire array formed on a common substrate can also be considered a microLED device 216. An active region 208 can be formed over the n-type semiconductor 206, and a p-type semiconductor 210 formed over the active region 208. The n-type semiconductor 206, active region 208, and p-type semiconductor 210 can be formed using an epitaxial growth process. In some embodiments, a first electrode 212, which can be referred to as a p-type electrode, can then be formed or deposited over the p-type semiconductor 210. Patterning and etching (e.g., dry etching) can be used to etch spaces to create separate microLED devices 216. For example, as shown in FIG. 3A, four separate microLED devices 216 are formed (although greater or fewer than this number of microLED devices may be formed). Second electrodes 214, which can also be referred to as n-type electrodes) can be deposited in the spaces 301 between active layers 208 of individual microLED devices 216 (e.g., one second electrode 214 is deposited and patterned in each space 301) and/or otherwise spaced laterally relative to the individual active layers 208 of the microLED devices 216 within the array.

Referring to FIG. 3B, after formation of the array of microLED devices 216 and their corresponding electrodes (first electrodes 212 and second electrodes 214), a dielectric 218 can be formed or deposited over the array of LED devices 216. In some embodiments, this dielectric 218 can be an oxide (e.g., SiO2) that laterally surrounds the microLED devices 216. The dielectric 218 can be planarized or thinned (e.g., using CMP) until the dielectric 218 is coplanar with the first electrodes 212 and the second electrodes 214 of the array of microLED devices 216.

In FIG. 3C, a DBR layer (e.g., DBR 220) can be formed over the planarized array of microLED devices 216. As described for FIG. 2C, the DBR layer is formed from multiple, alternating thin film layers of dielectric materials having relatively large and small refractive indices to reflect light, such as SiO₂, TiO₂, GaN, ZrO₂, SiN, etc. The DBR layer can then be etched, as shown in FIG. 3D, and those etched regions can be filled as shown in FIG. 3E with an electrically conductive material to form contacts 224, which can electrically connect to the first electrodes 212 and the second electrodes 214. In some embodiments, the contacts 224 are formed from the same material as the first electrode 212 and or/ the second electrode 214. In some embodiments, the contacts 224 can be formed from an optically transparent material, such as ITO. As described previously, these contacts 224 can be formed to have a width in a range between approximately 0.5 μm and 50 μm, such as about 0.5 μm to 3 μm, about 1 μm to 10 μm, or about 5 μm to 50 μm to minimize areas without DBR 220.

Referring to FIG. 3F, the structure, including the carrier member 201, the microLED devices 216, and the DBR 220 can then be inverted and directly bonded to a circuitry element 228, and particularly hybrid bonded with contacts 230, to form the microLED array assembly 300. The circuitry element 228 can include passive (e.g., wiring) or active (e.g., switching) circuitry 236, and the contacts 230 electrically communicate with the circuitry 236. In some embodiments, the bonding interface 234 can be between the DBR 220 and the circuitry element 228. The carrier member 201 can then be thinned or removed using a process such as grinding, polishing, and/or laser ablation, leaving the n-type semiconductor 206 layer on top of the microLED assembly 300, as shown in FIG. 3F. At this stage, the DBR 220 can reflect light that may be emitted from a bottom surface of the microLED devices 216, as indicated by the arrows in FIG. 3F. In some embodiments, the surface 302 of the n-type semiconductor 206 or any overlying cap layer can be textured (e.g., textured surface 304). Texturing the surface can improve the light extraction efficiency. If desired, the microLED array assembly 300 can singulated into individual emitter devices, such as microLED devices 216 with bonded circuitry, or smaller arrays with bonded circuitry.

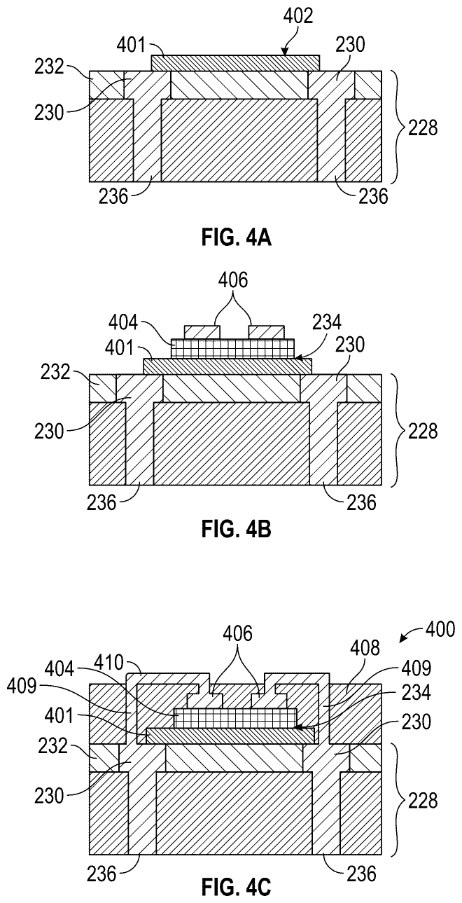

FIGS. 4A-4C illustrate a process of forming a microLED assembly 400, according to another embodiment. Unlike the processes illustrated in FIGS. 2A-2G and 3A-3F, the processes in FIGS. 4A-4C are implemented on the type of emitter structure that is traditionally wirebonded, but is adapted for application to a microLED assembly 400 that includes direct bonded elements. In FIG. 4A, a circuitry element 228 is provided and a DBR 401 can be formed (e.g., through deposition) over the circuitry element 228, where the circuitry element 228 includes contacts 230 embedded within a dielectric 232. The contacts 230 are in electrical communication with circuitry 236 (e.g., wiring or active devices) within the circuitry element 228. The DBR 401 can be treated to be suitable for direct bonding, such as by sufficient planarization, and may also be activated and/or terminated to leave a bonding surface 402 and can be patterned as shown.

With reference to FIG. 4B, an active device 404 can be bonded to the DBR 401 through a direct bond at the bond interface 234. The active device 404 for the illustrated microLED embodiment includes n-type and p-type semiconductor layers with an intervening active layer. For example, a microLED semiconductor layer structure can be fabricated on another substrate, singulated, and picked-and-placed onto the DBR 401. While both the active device 404 and the DBR 401 can be sufficiently planarized for direct bonding, one or both surfaces may be activated and/or terminated to facilitate bonding. Uniform direct bonding can be employed for the illustrated embodiment. Electrodes 406 can be formed on the active device 404. As noted for previously described embodiments, the electrodes 406 can be transparent conductors, such as ITO, because they are formed over at least part of the active device 404. In some cases, instead of forming the DBR on the circuitry element 228 and then direct bonding the microLED to the DBR, the microLED and DBR stack can be fabricated first and direct bonded to the circuitry element 228 afterward. For example, a wafer level DBR can be formed on or otherwise attached to an active device and then the unbound or free side (e.g., the side that is not coupled to the microLED) of the DBR can be directly bonded to the circuitry element 228.

As illustrated in FIG. 4C, a dielectric 408 can be formed over at least the electrodes 406, the active device 404, and the DBR 401. The dielectric 408 can be etched and the resulting spaces filled with an electrically conductive material (e.g., ITO, copper, etc.) to form vias 409 to the contacts 230 and the device electrodes 406, and traces 410 can be formed to electrically connect the vias 409, thus connecting contacts 230 in the circuitry element 228 to the electrodes 406. As with other embodiments, the emitting side of the resultant microLED assembly 400 can be capped and/or integrated with optical devices such as lenses.

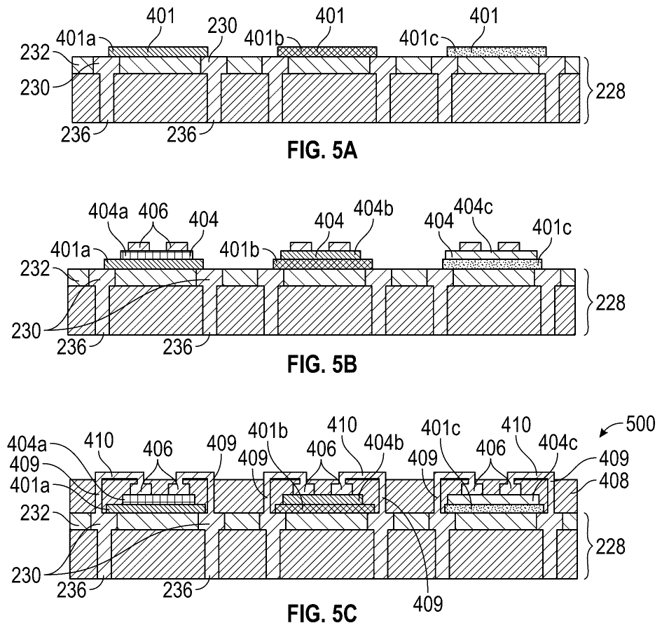

In some embodiments, and as shown in FIGS. 5A-5C, the process described with respect to FIGS. 4A-4C can be conducted to form a microLED array assembly 500. The active devices 404 can be formed prior to being bonded to the DBR 401, which can allow for the implementation of multi-colored microLEDs. All of the active devices 404 and DBRs 401 can be identical in some arrangements. However, in the illustrated example, three different DBRs (e.g., first DBR 401a, second DBR 401b, and third DBR 401c) may be formed (e.g., through deposition and patterning) on the circuitry element 228. The individual DBRs 401 can be formed such that the first DBR 401a can reflect a light of a first color (e.g., red); the second DBR 401b can reflect a light of a second color (e.g., green), and the third DBR 401c can reflect a light of a third color (e.g., blue). In some cases, a stack including a microLED and a DBR, with the DBR tuned to the emission wavelength of the microLED, can be fabricated first and the stack subsequently singulated and direct bonded to the circuitry element 228.

With reference to FIG. 5B, corresponding different ones of the active devices 404 can be directly bonded to the DBRs 401 (e.g., pick and place technique may be used). A first active device 404a can be disposed over the first DBR 401a, a second active device 404b can be disposed over the second DBR 401b, and a third active device 404c can be disposed over the third DBR 401c. The first active device 404a can produce light of a first color, the second active device 404b can produce light of a second color, and the third active device 404c can produce light of a third color. In some embodiments, the first, second, and third colors can be the same. In the illustrated embodiment, the first, second, and third colors are different from one another (e.g., first color can be red, second color can be green, and third color can be blue). Electrodes 406, both anodes and cathodes, can be formed over the individual active devices 404 (e.g., first active device 404a, second active device 404b, and third active device 404c).

As illustrated in FIG. 5C, and like the process shown in FIG. 4C, a dielectric 408 can be formed over the electrodes 406, the active devices 404a-404c, and the DBRs 401a-401c. The dielectric 408 can be etched and the resulting spaces filled with an electrically conductive material (e.g., copper or ITO) to form vias 409, and traces 410 can be formed to electrically connect the vias 409, thus connecting the underlying contacts 230 in the circuitry element 228 to the electrodes 406. As with other embodiments, the emitting side of the resultant microLED array assembly 500 can be capped and/or integrated with optical devices such as lenses. It will be appreciated that, by combining pick-and-place with direct bonding technologies, the array can include multi-color pixels as shown, and integrating DBRs 401a-401c, can minimize losses from backside emissions. In some embodiments, one or more of electrodes 406 are electrically connected to the contacts 230 in the circuitry element 228 using wire bonds.

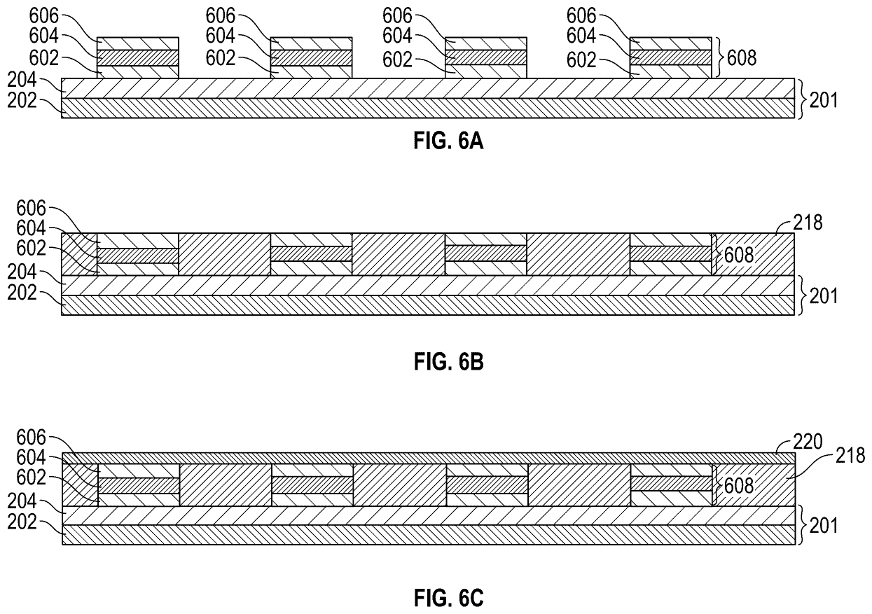

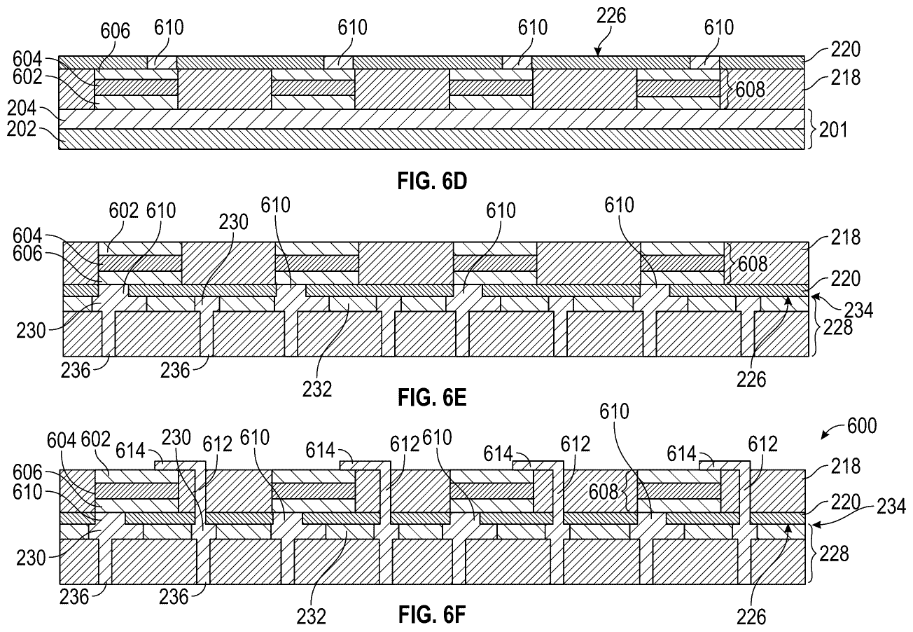

FIGS. 6A-6F illustrate a process for fabricating an optical emitter structure (e.g., microLED assembly 600), according to another embodiment. The process illustrated in FIGS. 6A-6F is similar to the process illustrated in FIGS. 2A-2G and 3A-3F, except that in FIGS. 6A-6F, the microLED assembly 600 has a vertical type of arrangement, that is, upper and lower electrodes, or cathode and anode, can be coextensive and contacted from opposite sides. As shown in FIG. 6A, a plurality of microLEDs devices 608, including electrodes, can be formed over a carrier member 201 through a process including epitaxial growth, electrode deposition, patterning, and etching. For example, a first electrode 602 can be deposited or formed over the carrier member 201. In some cases, the first electrode 602 can be a transparent conductive oxide (TCO) such as ITO. In some cases, the first electrode 602 can be a heavily doped semiconductor layer that can also serve as an epitaxial template for the semiconductor layers of an active device 604. The active device 604 can include an n-type semiconductor, a p-type semiconductor and an active region (e.g., MQW) between the n-type semiconductor and the p-type semiconductor. A second electrode 606 can be formed or deposited over the active device 604. The layers so formed can be etched to form the individual microLED devices 608. FIG. 6A illustrates four such individual microLED devices 608. In some cases, greater or fewer than four may be included.

Referring to FIG. 6B, a dielectric 218 can be formed over the microLED devices 608. In some embodiments, the dielectric 218 can comprise one or more layers of dielectric layers (of one or more materials). In some embodiments, the dielectric 218 can be an oxide (e.g., SiO₂). The dielectric 218 can be planarized (e.g., using a CMP process) until it is coplanar with the second electrode 606.

In FIG. 6C, a DBR 220 is formed over the microLED devices 608. In FIG. 6D, the DBR 220 is etched, and the etched portions are filled with an electrically conductive material, forming the contacts 610, which provide electrical contact with the second electrodes 606. In some embodiments, the contacts 610 can include a metal (e.g., copper). In some embodiments, the contacts 610 can include a TCO (e.g., ITO). In some embodiments, a via (not shown) may be formed through the microLED device 608 and filled with conductive material to form electrical contact with the first electrode 602 and a second contact within the DBR 220 (not shown). In some cases, the contact 610 and the second contact can be implemented as two electrodes on a same side of the microLED for hybrid bonding.

After formation of the DBR 220 with the contacts 610, which are coplanar with (e.g., are coextensive with a thickness of) the DBR 220, the surface 226 of the DBR 220 can be prepared for hybrid bonding. The DBR 220 and embedded contacts 610 thus serve as a hybrid bonding layer.

As shown in FIG. 6E, the substrate of FIG. 6D is then inverted and a hybrid bond is formed between the DBR 220 and a circuitry element 228 at the bonding interface 234. The carrier member 201 can be removed, as shown.

As shown in FIG. 6F, the dielectric 218 can be etched and filled with an electrically conducting material, to form interconnects or vias 612. The vias 612 are electrically connected to the contacts 230 and traces 614, which are electrically connected to the first electrodes 602. Accordingly, in the resultant microLED assembly 600, the lower electrodes 606 are interconnected through hybrid bonding with the circuitry element 228, while the upper electrodes 602 are interconnected through more traditional vias 612 formed after hybrid bonding, whereas in FIGS. 2A-3F all of the electrodes are interconnected through hybrid bonding. As with other embodiments, the emitting side of the resultant microLED assembly 600 can be capped and/or integrated with optical devices such as lenses.

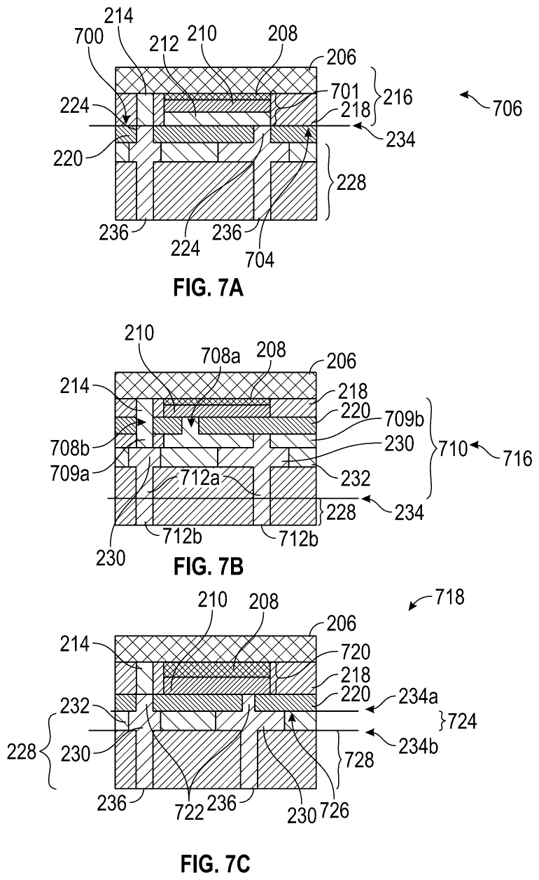

FIGS. 7A-7C are schematic cross-sections illustrating alternative ways of forming an optoelectronic illumination source (e.g., microLED assembly) having an integrated DBR layer (e.g., DBR 220 or 401). Although FIGS. 7A-7C illustrate the formation of one light emitting device, in some cases, arrays of light emitting devices can be formed using the processes described herein.

FIG. 7A illustrates an embodiment like that of FIG. 2G, but instead of having the bonding interface 234 between the DBR 220 and the circuitry element 228, the bonding interface 234 can instead be between the DBR 220 and the microLED device 216. In this embodiment, the DBR 220 can be formed over the circuitry element 228. As described herein, the DBR 220 can be etched and the contacts 224 formed such that the contacts 224 are in electrical contact with the circuitry 236 of the circuitry element 228. The DBR surface 700 can be prepared for direct bonding. The microLED device 216 can be separately formed as described herein. For example, through an epitaxial growth process, a first semiconductor layer such as an n-type semiconductor 206 can be formed over a carrier member 201 (see FIG. 2A or 3A), an active layer (e.g., active region 208) can be formed over the n-type semiconductor 206, and second semiconductor layer such as a p-type semiconductor 210 can be formed over the active layer (e.g., active region 208). A first electrode 212 can be formed over the p-type semiconductor 210 and an etching step can take place to form a microLED mesa structure 701. A second electrode 214 can subsequently be formed over the n-type semiconductor 206, such that it is laterally spaced with respect to the microLED mesa structure 701 and in electrical contact with the n-type semiconductor 206. A dielectric 218 is deposited over the microLED mesa structure 701, the first electrode 212, and the second electrode 214, and it is thinned until it is coplanar with the first electrode 212 and the second electrode 214, forming a microLED back surface 704. The microLED back surface 704 can be prepared for bonding. The microLED back surface 704 can be hybrid bonded to the DBR surface 700, which forms the microLED assembly 706. The carrier member 201 can be removed after hybrid bonding, and the emitting (upper) surface of the microLED assembly 706 can be capped and/or integrated with optical devices such as lenses.

Referring to FIG. 7B, in some embodiments, instead of forming the first electrode 212 directly over the p-type semiconductor 210 as is illustrated in FIG. 7A, the DBR 220 can be formed directly over the p-type semiconductor 210, and a first contact 708a formed through the DBR 220 can directly contact the p-type semiconductor 210 without an intervening electrode. A second contact 708b can also be formed through the DBR 220 to electrically connect the n-type semiconductor 206 by way of the second electrode 214. In other arrangements, the second contact 708b can extend through the DBR 220 and the surrounding insulator 218 can make direct contact with n-type semiconductor 206 without an intervening contact. The contacts 708a, 708b and second electrode 214 can be transparent conductors, such as ITO. Although only one contact 708a and 708b of each type is depicted in FIG. 7B, two or more such contacts can be formed. Furthermore, at the same time as filling the openings for the contacts (e.g., in a dual damascene process) or in a separate process, the transparent conductor can include contact extensions 709a and/or traces 709b over the DBR 220, such that the transparent conductor can also serve as RDL. In some embodiments, the various layers and elements can be grown and/or deposited to form a first sub-assembly 710. The first sub-assembly 710 can further include additional metallization layer(s) which can comprise copper, such as contact pads 712a that are in electrical contact with the contacts 230. The first sub-assembly 710 can be inverted and directly bonded, particularly hybrid bonded, to a circuitry element 228 having contact pads 712b, such that the contact pads 712a, 712b can be directly bonded to one another along the bonding interface 234 and form the microLED assembly 716.

With reference to FIG. 7C, another embodiment of a microLED assembly 718 is shown without a separate first electrode 212. For example, as shown in FIG. 7C, a microLED mesa structure 720 can be formed over an n-type semiconductor 206. A second electrode 214 can be formed directly over the n-type semiconductor 206, and a dielectric 218 can be formed over a prepatterned second electrode 214 and the microLED mesa structure 720. After the dielectric 218 is thinned to be coplanar with the second electrode 214 and the LED mesa structure 720, a DBR 220 can be formed directly over the second electrode 214 and the microLED mesa structure 720. The DBR 220 can be etched and filled with conductive material to form contacts 722, which are electrically connected to the second electrode 214 and the p-type semiconductor 210 of the microLED mesa structure 720. The contacts 722 that are electrically connected to the p-type semiconductor 210 can be substantially smaller than a surface area of the microLED mesa structure 720. Although only one contact 722 is depicted in FIG. 7C to connect the p-type semiconductor 210, two or more such contacts can also be formed that are distributed over the area of the p-type semiconductor 210. The DBR 220 with its contacts 722 form a DBR surface 726, which can be prepared for direct bonding (e.g., polishing, etc.). The DBR surface 726 can be directly bonded along a bonding interface 234a to a bonding layer 724, including a dielectric 232 and contacts 230 of a circuitry element 228. The contacts 230 can be larger in size than the contacts 722 in the DBR 220, which can help facilitate alignment of the contacts 722 in the DBR 220 with the circuitry element 228. Alternatively, the bonding layer 724 is provided over the DBR 220 as part of the optical device, which is then hybrid bonded along a bonding interface 234b to a bonding layer 728 of the circuitry element. In some embodiments, the bonding layer 728 comprises pads or contacts that connect to circuitry 236 within the circuitry element 228 (e.g., a CMOS or a TFT backplane). FIG. 7C represents two different embodiments: one embodiment in which the hybrid bonding interface 234a is at the DBR 220 and the bonding layer 724 is part of the circuitry element 228; and a second embodiment in which the DBR 220 is buried below the bonding layer 724, which is part of the microLED device 218 and is bonded at the hybrid bonding interface 234b.

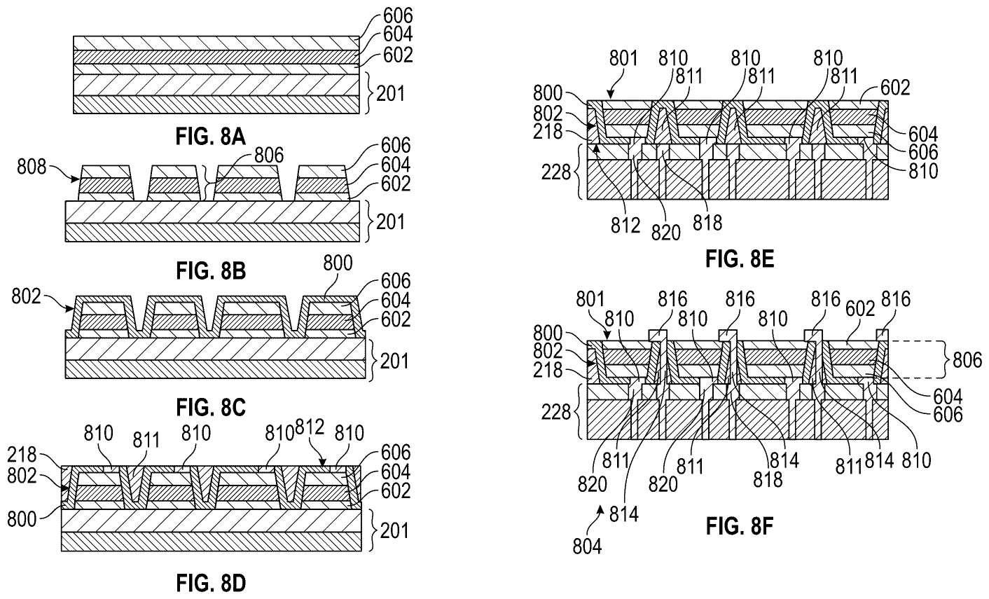

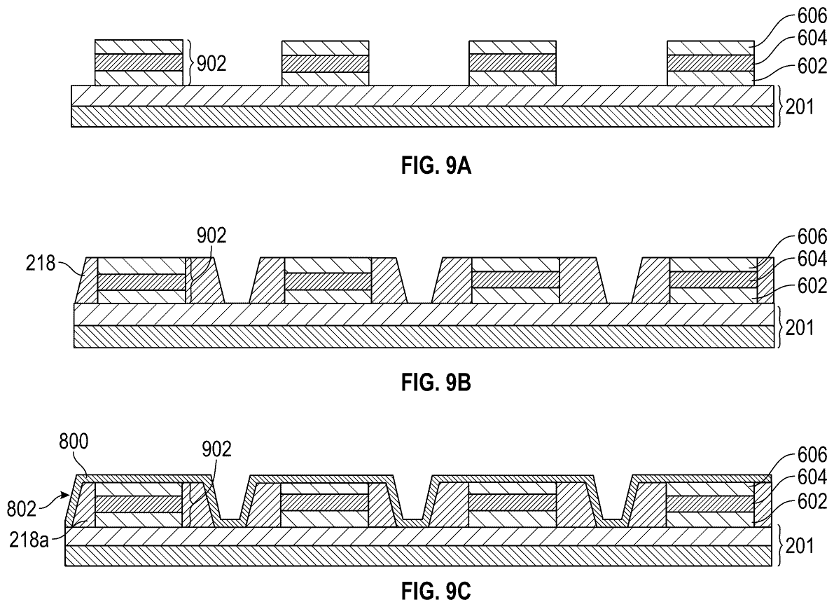

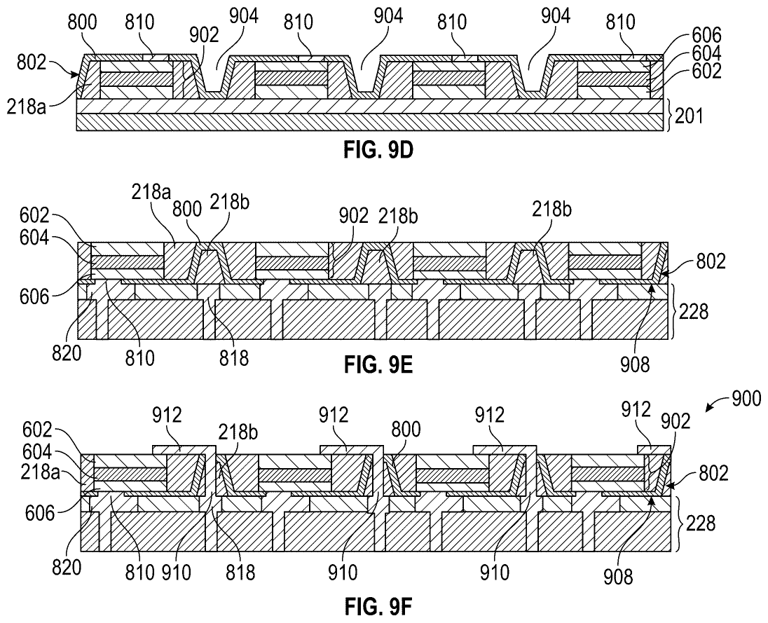

Referring to FIGS. 8A-9F, in some embodiments, to further improve the brightness of the light to be emitted from the optical emitters (e.g., microLEDs), additional reflective structures may be included to conform to (e.g., laterally surround) the microLED structures and facilitate reflecting light coming from the bottom and sides of the microLEDs to an output surface 801 of the microLEDs.

With reference to FIGS. 8A-8F, for example, a DBR 800 can be formed over one or more microLED devices 806, where the DBR 800 includes sloped sidewalls 802. To fabricate a microLED assembly 804 having a DBR 800 and sloped sidewalls 802, a first electrode 602 can be formed over a carrier member 201, semiconductor layers of an active device 604 can be formed over the first electrode 602, and a second electrode 606, which may be a TCO or a doped semiconductor, can be formed over the active device 604, as was described for FIG. 6A. Unlike in FIG. 6A, an etch may be selected to create active devices 604 within the microLED devices 806 having sloped sides 808 (e.g., FIG. 8B). In FIG. 8C, a DBR 800 having sloped sidewalls 802 can be formed over the microLED devices 806. For example, the DBR 800 can be deposited on the sloped sidewalls 808 of the microLED devices 806. Where the DBR 800 is adjacent to the second electrode 606 (or the carrier member 201), an additional etch step can be performed and the voids filled with an electrically conductive material (e.g., copper, etc.) to form DBR contacts 810 to the second electrodes 606. A dielectric 218 is formed over the DBR 800 and thinned or planarized until it is coplanar with the DBR 800, as shown in FIG. 8D. Dielectric-filled spaces 811 are created between the microLED devices 806. The surface 812 of the dielectric 218 that was thinned is then prepared for direct bonding, and the surface 812 can be inverted and directly bonded, particularly hybrid bonded to a circuitry element 228 (e.g., with active circuitry like a CMOS circuit or a TFT backplane, or passive circuitry like a passive interposer), as shown in FIG. 8E. The DBR contacts 810 may directly bond to second circuitry contacts 820 of the circuitry element 228, while the dielectric DBR 800 and exposed dielectric-filled spaces 811 directly bond to dielectric bonding surfaces of the circuitry element 228. The carrier member 201 can be removed at this stage as shown in FIG. 8E. FIG. 8F illustrates that interconnects 814 can be formed through the dielectric-filled spaces 811 between individual microLED devices 806, and that traces 816 can be formed to electrically contact the first electrodes 602. The traces 816 may electrically connect to the interconnects 814 and first circuitry contacts 818 of the circuitry element 228.

FIGS. 9A-9F illustrate a process for fabricating a microLED assembly 900, according to another embodiment. Unless otherwise noted, like reference numbers are employed to refer to the components of FIGS. 9A-9F that are the same as or generally similar to the components of FIGS. 8A-8F, and alternatives noted above with respect to FIGS. 8A-8F are likewise applicable to the embodiment of FIGS. 9A-9F. Unlike FIGS. 8A-8F, in which the DBR 800 is fabricated prior to the formation of the dielectric 218, in the embodiment of FIGS. 9A-9F, at least a portion of the dielectric 218 is fabricated prior to the formation of the DBR 800. Accordingly, the microLED devices 902 can be formed on the carrier member 201 with straight sidewalls, or can be picked and placed onto the carrier member 201, and the sloped sidewalls subsequently provided by dielectric sidewalls 218a.

FIG. 9A shows the formation of microLED devices 902, which may be formed from dry etching an active device 604 (described herein). In FIG. 9B, a dielectric 218a can be formed over the microLED devices 902. The dielectric 218a can undergo a wet etch step to form sloped sides. The dielectric 218a can also be thinned or planarized (e.g., undergo CMP process) to make it coplanar with the microLED devices 902. In some cases, wet etching the dielectric 218a can occur before the thinning step. In some cases, thinning the dielectric 218a can occur before the wet etching step. In FIG. 9C, the DBR 800 can be formed over the microLED devices 902 and the dielectric 218a, where the DBR 800 includes one or more sloped sidewalls 802. As illustrated, the DBR 800 conforms to the shape of the layer over which it is disposed (e.g., laterally surrounds the plurality of microLED devices 902). As shown in FIG. 9D, the DBR 800 has surfaces over the microLED devices 902 parallel to the carrier member 201, which can be etched and filled to form DBR contacts 810. As shown in FIG. 9E, the angled/sloped spaces 904 between neighboring microLED devices 902 can be filled with a further dielectric material 218b. In some cases, the dielectric material 218b is the same as that of dielectric 218. The DBR surface 908, including the parallel portions of the DBR layer 800, the DBR contacts 810, and the dielectric material 218b, are prepared for a hybrid bonding step. The optical emitters are inverted and the DBR surface 908 is hybrid bonded to a circuitry element 228 and the carrier member 201 can be removed from the emitting side of the assembly 900. Following the removal of the carrier member 201, interconnects 910 can be formed through the dielectric material 218b in the angled/sloped spaces 904 and traces 912 can be formed to electrically contact the microLED devices 902 (e.g., FIG. 9F). The traces 912 may comprise a transparent conductor and can electrically connect to the interconnects 910 and first circuitry contacts 818. The DBR contacts 810 may be directly bonded to the second circuitry contacts 820 by the hybrid bonding process.

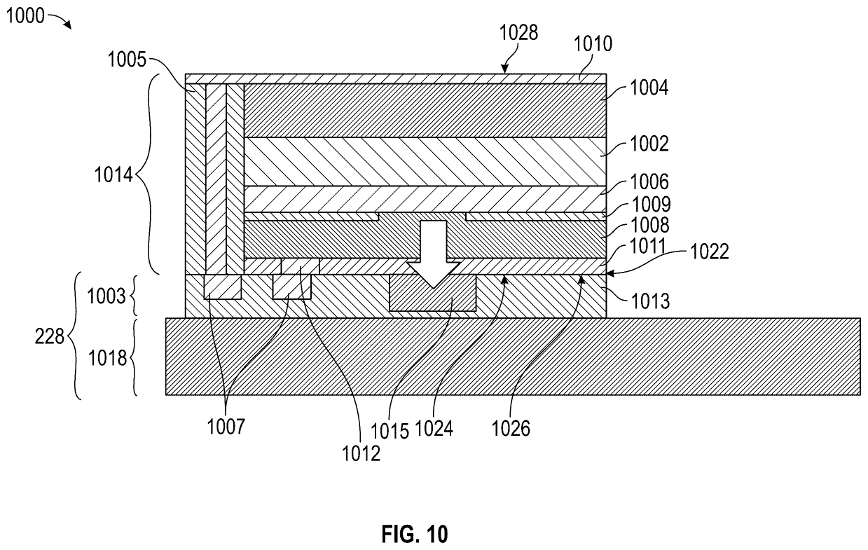

As shown in FIG. 10, in some embodiments, the DBR as a bonding layer can be integrated into other types of optoelectronic illumination sources, such as the illustrated laser or laser diode (e.g., VCSEL). Although FIG. 10 illustrates an example process for forming a VCSEL, in some cases, similar processes can be implemented to form other types of lasers or laser diodes. For example, these may include an edge-emitting laser (EEL), a photonic-crystal surface-emitting laser (PCSEL), etc. The process for forming a laser diode (e.g., a laser diode structure 1000) can be similar to the process for forming the microLED structure 200 shown in FIG. 2G. Unlike the microLED structure 200 in FIG. 2G, the laser diode structure 1000 can include multiple DBRs (three illustrated), each including multiple alternated layers tuned to reflect particular wavelengths. For example, in FIG. 10, a laser diode structure 1000 can include a first DBR 1002 formed over a substrate 1004 (e.g., GaAs, or doped GaAs). In some cases, the first DBR 1002 is an n-type Bragg reflector, such as AlGaAs layers alternated with GaAs layers with highly tuned reflectivity for the emission frequency of greater than 99.5%, such as greater than or equal to 99.9%. An active device 1006 is formed (e.g., through epitaxial growth) over the first DBR 1002. The active device 1006 can include a high gain optical cavity having at least one MQW. A second DBR 1008 can be formed over the active device 1006. In some cases, the second DBR 1008 is a p-type Bragg reflector, such as AlGaAs/GaAs layers with lower reflectivity for the emission wavelength, such as about 95% to about 99.4%, or about 98.2% to 99.2%. The second DBR 1008 is patterned to include an oxide aperture 1009 adjacent the optical cavity of the active device 1006. In some embodiments, no oxide aperture is included. A first electrode 1010 can be formed on a surface of the substrate 1004 opposite the surface on which the first DBR 1002 is formed. In some cases, the first electrode 1010 can be optically transparent and electrically conductive (e.g., ITO). In some cases, the first electrode 1010 can be a metal (e.g., copper).

A third DBR 1011 is illustrated over the second DBR 1008 and can be formed as a dielectric stack (e.g., alternated oxide/TiN layers). Similar to the process shown in FIGS. 2A-2G, the third DBR 1011 can be etched and filled to form a plurality of contacts 1012 through the third DBR 1011 and/or one or more vias 1005 to facilitate electrical connection between the conductive first and second DBRs 1002 and 1008 with a circuitry element 228 (e.g., a waveguide element 1003 in or on an interposer 1018). Although not shown, in some cases, a second electrode may be included between the second DBR 1008 and the third DBR 1011. In some cases, the second electrode may be a ring electrode. In some cases, the second electrode may be formed from an optically transparent and electrically conductive material (e.g., ITO). The contacts 1007 in the waveguide element 1003 and/or interposer 1018 can connect to control circuitry either in the waveguide element 1003 or interposer 1018, or in other devices communicating with the waveguide element 1003 and/or interposer 1018. In some embodiments, the plurality of contacts 1012 can be formed of an optically transparent and electrically conductive material (e.g., ITO), or can be a metal such as copper, as the contact occupies a small percentage of the surface area of the emitting surface.

As illustrated in FIG. 10, the waveguide element 1003 can include a dielectric 1013 in which a waveguide 1015 may be formed at the bond interface. The waveguide element 1003 is coupled to the laser diode device 1014 such that light emitted from the laser diode device 1014 can propagate into the waveguide 1015. In some embodiments, the waveguide 1015 includes an optical grating coupler to facilitate the coupling of light from the laser diode device 1014 to the circuitry element 228 comprising at least the waveguide element 1003 in or on an interposer 1018. In some cases, the waveguide 1015 is a silicon waveguide. In some embodiments, the dielectric 1013 can be an oxide or a nitride.

In some embodiments, an interposer 1018 can be directly bonded to a laser diode device 1014 along the bonding interface 1022, which includes a bonding surface 1024 (e.g., direct bonding or hybrid bonding surface) of the third DBR 1011. The laser diode device 1014 can include at least the active device 1006 and the first electrode 1010. In some cases, the interposer 1018 can include an optical waveguide to receive signals from the laser diode device 1014. In the illustrated embodiment, the laser diode 1014 can be directly bonded to a waveguide element 1003 that is part of or bonded to the interposer 1018, and the waveguide element 1003 also can include contacts to route signals. The laser diode device 1014 can additionally have its surface 1028 prepared for direct bonding and be direct bonded to a circuitry element (not shown). In some embodiments, a surface 1028 of the laser diode structure 1000 may be bonded to an interposer (not shown). In the configuration of laser diode structure 1000, as shown in FIG. 10, light can be transmitted through a surface 1026 of the laser diode device 1014 into the waveguide element 1003.

Although FIG. 10 illustrates an embodiment having one laser diode device, in some cases, an array of laser diode devices can be formed.

In some cases, a laser diode structure utilizing one or more DBRs as direct bonding layers can be implemented in a co-packaged optics solution. For example, a laser diode structure 1000 may be directly bonded to an interposer, or to a waveguide element on or part of the interposer, through which it can communicate with a processor and a high bandwidth memory (HBM) die. In another example, a laser diode structure 1000 (or switch) can serve as a part of a PIC, and can be co-packaged with an EIC, such as for controlling the laser diode structure 1000.

The embodiments and features disclosed herein with respect to optoelectronic illumination sources integrating one or more DBRs is advantageous in the general fabrication of optical emitters, and particularly beneficial in the development of co-packaged optics solutions. In some cases, the DBRs can include a plurality of electrical contacts that extend through a thickness of an individual DBR, which can provide the electrical pathways for signal and power between a circuitry element and the light emitting device (e.g., microLED, VCSEL, etc.). In some cases, the DBRs can be implemented as direct or hybrid bonding layers, which can eliminate relatively high-temperature AuSn eutectic bonding, thereby helping to reduce thermal stresses. Further, the one or more DBRs as bonding layers can be used together with optically transparent electrodes and contacts. Beneficially, the optically transparent contacts can be embedded within one or more DBRs and the dimensions of these contacts may be kept at a minimum which can reduce the amount of light loss as more of the light will reflect off the DBR into the desired light output pathway. Reducing light loss can result in improved brightness of the optical emitters. In some cases, where the embedded contacts may be metal (e.g., not optically transparent), the minimization of the widths of the contacts can maximize the amount of light reflected by the DBR. In some cases, the DBRs to be integrated may be fabricated to allow for precise tuning to maximize the reflection of wavelengths of interest.

In one aspect, the techniques described herein relate to an optoelectronic illumination source, including an array of light emitting devices, a distributed Bragg reflector (DBR) layer including a direct bonding surface, and a circuitry element including a first circuit and a plurality of contacts. The array of light emitting devices includes a first device having a first electrode and second electrode. The plurality of contacts includes a first contact electrically coupled to the first electrode and a second contact electrically coupled to the second electrode. The first device is directly bonded to the first circuit through the direct bonding surface of the DBR layer, and a continuous portion of the DBR layer covers a majority of a surface of the first device.

In some embodiments, the DBR layer includes a first surface disposed over the first electrode and a second surface that includes the direct bonding surface and is opposite the first surface. In some embodiments, the optoelectronic illumination source further includes a hybrid bond between the direct bonding surface and the circuitry element.

In some embodiments, the DBR layer includes a first surface disposed over the circuitry element and a second surface that includes the direct bonding surface and is opposite the first surface. In some embodiments, the optoelectronic illumination source further includes a direct bond between the direct bonding surface and the first device.

In some embodiments, the DBR layer includes a plurality of sidewalls and conforms to the array of light emitting devices. In some embodiments, the optoelectronic illumination source further includes a dielectric layer disposed over the array of light emitting devices, and the DBR layer overlies the dielectric layer and the array of light emitting devices. In some embodiments, the techniques described herein relate to an optoelectronic illumination source where the plurality of sidewalls includes sloped sidewalls.

In some embodiments, the array of light emitting devices includes a surface to output light, and the surface includes a textured surface.

In some embodiments, at least the first electrode or the second electrode includes an optically transparent and electrically conducting material. In some embodiments, at least the first electrode or the second electrode includes a transparent conductive oxide (TCO)r.

In some embodiments, the DBR layer includes a plurality of DBR contacts including a first DBR contact. The plurality of DBR contacts is coextensive with the DBR layer, and the first DBR contact has a width in a range between approximately 0.5 μm and 50 μm.

In some embodiments, the circuitry element includes a CMOS driver or a TFT backplane, and the array of light emitting devices includes an array of microLEDs.

In some embodiments, the DBR layer includes a plurality of film layers including at least one of SiO2, TiO2, GaN, ZrO2, or SiN.

In some aspects, the techniques described herein relate to a microLED structure including an array of light emitting diodes (LEDs) including a first LED, a circuitry element including a first circuit, and a distributed Bragg reflector (DBR) layer between the first LED and the first circuit. The DBR layer includes a plurality of contacts coextensive with the DBR layer, and the plurality of contacts electrically connects the first circuit to the first LED. The first LED is coupled to the first circuit through a direct bonding surface.

In some embodiments, the microLED structure further includes a direct bonding interface including the direct bonding surface. In some embodiments, the direct bonding interface is between the DBR layer and the circuitry element. In some embodiments, the direct bonding interface is between the DBR layer and the first LED. In some embodiments, the array of LEDs includes a second LED. The first LED emits light of a first color and the second LED emits light of a second color that is different than the first color. In some embodiments, the DBR layer includes at least a first DBR and a second DBR, where the first DBR reflects light of the first color, and the second DBR reflects light of the second color.

In some embodiments, the first LED includes a first electrode having an optically transparent and electrically conducting material. In some embodiments, the first electrode includes indium tin oxide (ITO). In some embodiments, the first electrode extends across a surface of the first LED. In some embodiments, the DBR layer includes a first surface and a second surface opposite the first surface. The first surface is adjacent to a surface of the first electrode, and the second surface includes the direct bonding surface.

In some embodiments, the circuitry element includes a CMOS driver or a TFT backplane.

In some embodiments, the DBR layer includes a plurality of film layers including at least one of SiO₂, TiO₂, GaN, ZrO₂, or SiN.

In some embodiments, the DBR layer includes a plurality of sidewalls and laterally surrounds each LED of the array of LEDs. In some embodiments, the microLED structure further includes a dielectric layer disposed over the array of LEDs, and the DBR layer substantially encapsulates the dielectric layer and a backside of the array of LEDs.

In some embodiments, the microLED structure includes a light-emitting surface to output light generated by the microLED structure, and the light-emitting surface includes a textured surface.

In some aspects, the techniques described herein relate to a method of forming an optical emitter, the method including forming an optical emitter active region and at least a first electrode on a substrate, forming a distributed Bragg reflector (DBR) layer over the optical emitter active region, and forming a plurality of first contacts coextensive in thickness with the DBR layer. The DBR layer includes a first side coupled to the optical emitter active region and a second side opposite the first side. The method further includes polishing the second side of the DBR layer to form a hybrid bonding layer.

In some embodiments, the method further includes depositing the first electrode over the optical emitter active region and a second electrode over the substrate. In some embodiments, the first electrode is optically transparent. In some embodiments, the first electrode includes indium tin oxide (ITO). In some embodiments, the second electrode is laterally spaced relative to the optical emitter active region.

In some embodiments, the method further includes forming a hybrid bond between the hybrid bonding layer of the DBR layer and a circuitry element. In some embodiments, the circuitry element includes a CMOS driver or a TFT backplane.

In some embodiments, the method further includes surrounding the optical emitter active region with the DBR layer, and the DBR layer includes a plurality of sidewalls.

In some embodiments, forming the plurality of first contacts includes etching and filling etched regions in the DBR layer to form individual contacts of the plurality of first contacts. The individual contacts can have widths in a range between approximately 0.5 μm and 50 μm.

In some embodiments, the method further includes forming a laser diode that includes the optical emitter active region. The DBR layer is disposed over the laser diode. In some embodiments, the method further includes hybrid bonding the DBR layer to a circuitry element that includes a waveguide element to receive light from the laser diode.

In some embodiments, forming the optical emitter active region includes forming a microLED active region.

In some aspects, the techniques described herein relate to an optoelectronic light emitting device including a first semiconductor substrate, a first light emitting device, and a DBR layer having a first side and a second side opposite the first side. The first side is disposed over the first light emitting device, and the DBR layer includes at least a first contact in electrical communication with an active region of the first light emitting device. At least the first contact is coextensive in thickness with the DBR layer, and the second side of the DBR layer includes a hybrid bonding surface to directly bond the DBR layer to a substrate including contacts.

In some embodiments, the optoelectronic light emitting device further includes a first electrode between the first light emitting device and the DBR layer. The first electrode is in electrical communication with the first contact and includes an optically transparent and electrically conducting material. In some embodiments, the first electrode extends across a surface of the first light emitting device.

In some embodiments, the substrate including contacts includes an interposer, a CMOS driver or a TFT backplane.

In some embodiments, the DBR layer includes a plurality of sloped sidewalls surrounding the first light emitting device.

In some embodiments, the optoelectronic light emitting device further includes a first dielectric layer disposed over the first semiconductor substrate. The first dielectric layer encapsulates the first light emitting device, a first electrode, and a second electrode. In some embodiments, the first side of the DBR layer is disposed over the first dielectric layer.

In some embodiments, the first light emitting device is a laser diode device. In some embodiments, an optoelectronic illumination source includes the optoelectronic light emitting device and a circuitry element, where the DBR layer is hybrid bonded to the circuitry element. In some embodiments, the circuitry element includes a waveguide optically coupled to receive light from the laser diode device.

In some embodiments, the first light emitting device is a microLED.

In some aspects, the techniques described herein relate to a method of forming a microLED structure, the method including forming a plurality of DBR structures including a first DBR structure over a substrate. The substrate includes a plurality of active devices and a plurality of first electrodes including a first electrode and a second electrode. The method further includes processing a top surface of the first DBR structure to form a bonding surface, directly bonding an LED to the top surface of the first DBR structure, and forming a plurality of second electrodes over the LED. The processing includes polishing the top surface. The LED emits a first color light, and the plurality of second electrodes includes a third electrode and a fourth electrode. The method further includes encapsulating the LED and the plurality of DBR structures with a first dielectric, and forming one or more contacts through the first dielectric to electrically connect the first electrode with the third electrode and the second electrode with the fourth electrode.

In some embodiments, the substrate is a CMOS driver or a TFT backplane.

In some embodiments, the plurality of DBR structures includes a second DBR structure, and a second LED to emit a second color light different than the first color light is directly bonded to the second DBR structure. The first DBR structure reflects the first color light, and the second DBR structure reflects the second color light.

In some aspects, the techniques described herein relate to a method of forming a microLED structure, the method including forming a first electrode over a substrate, forming a light emitting diode (LED) layer over the first electrode, depositing a second electrode over the LED layer, forming a first dielectric layer that is disposed over the substrate to encapsulate the first and second electrodes and the LED layer, thinning the first dielectric layer to expose the second electrode, forming a DBR layer over the first dielectric layer and second electrode, forming a bonding interface, and hybrid bonding the bonding interface to circuitry. The DBR layer includes a plurality of contacts, and the bonding interface includes a polished surface of the DBR layer.

In some embodiments, the first electrode includes an optically transparent and electrically conducting material. In some embodiments, the first electrode extends across a surface of the LED layer.

In some embodiments, the circuitry includes a CMOS driver or a TFT backplane.

In some embodiments, the method further includes laterally surrounding the LED layer with the DBR layer. The DBR layer includes a plurality of sloped sidewalls.

In some aspects, the techniques described herein relate to a method of forming a microLED structure, the method including forming an array of light emitting diodes (LEDs) including a first LED, and forming a first distributed Bragg reflector (DBR) on a circuitry element having a first circuit. The first DBR, which is between the circuitry element and the first LED, includes a direct bonding surface, and a continuous portion of the first DBR covers a majority of a surface of the first LED. The method further includes directly bonding the first LED to the direct bonding surface.

In some embodiments, the method further includes forming a plurality of contacts coextensive with a thickness of the first DBR. In some embodiments, the method further includes etching and filling etched regions in the first DBR to form individual contacts of the plurality of contacts. The individual contacts have widths in a range between approximately 0.5 μm and 50 μm. In some embodiments, the method further includes electrically connecting the first circuit to the first LED through the plurality of contacts.

In some embodiments, the method further includes forming a second DBR on the circuitry element. The array of LEDS includes a second LED, where the first LED emits light of a first color and the second LED emits light of a second color that is different than the first color. The first DBR reflects light of the first color and the second DBR reflects light of the second color.

In some embodiments, the surface of the first LED includes a first electrode including an optically transparent and electrically conducting material. In some embodiments, the first electrode extends across the surface of the first LED.

In some embodiments, the circuitry element includes a CMOS driver or a TFT backplane.

In some aspects, the techniques described herein relate to a method of forming a microLED structure, the method including forming an array of light emitting diodes (LEDs) including a first LED, and forming a distributed Bragg reflector (DBR) layer between the array of LEDs and a circuitry element having a first circuit. The DBR layer includes a plurality of contacts coextensive with a thickness of the DBR layer. The method further includes electrically connecting the first circuit to the first LED through the plurality of contacts, and coupling the first LED to the first circuit through a direct bonding interface.

In some embodiments, the method further includes hybrid bonding the DBR layer to the circuitry element, where the direct bonding interface is between the DBR layer and the circuitry element.

In some embodiments, the method further includes direct bonding the DBR layer to the first LED, where the direct bonding interface is between the DBR layer and the first LED. In some embodiments, the array of LEDs includes a second LED. The first LED emits light of a first color and the second LED emits light of a second color, where the first color is different than the second color. In some embodiments, the DBR layer includes at least a first DBR and a second DBR, where the first DBR reflects light of the first color, and the second DBR reflects light of the second color.

In some embodiments, the first LED includes a first electrode including an optically transparent and electrically conducting material. In some embodiments, the first electrode extends across a surface of the first LED.

In some embodiments, the circuitry element includes a CMOS driver or a TFT backplane.

In some embodiments, the method further includes hybrid bonding the DBR layer to an LED bonding surface of the first LED. The LED bonding surface includes a first electrode surface, a second electrode surface, and a dielectric.

In some embodiments, the method further includes forming a first electrode and a second electrode of the first LED. The first electrode is between the DBR layer and the circuitry element and is in electrical contact with a first DBR contact of the plurality of contacts. The first DBR contact is in electrical contact with a semiconductor layer of the first LED, and the second electrode extends through the DBR layer. The circuitry element is directly bonded to the first electrode and the second electrode.

In some embodiments, the method further includes forming the DBR layer directly over a semiconductor layer of the first LED, and etching and filling the etched regions of the DBR layer to form the plurality of contacts. The plurality of contacts includes a first contact and a second contact, where the first contact electrically contacts the semiconductor layer of the first LED and a first circuitry element contact, and the second contact electrically contacts an electrode of the LED and a second circuitry element contact. The first contact and the second contact are directly bonded to the first circuitry element contact and the second circuitry element contact.

In some embodiments, the method further includes laterally surrounding the array of LEDs with the DBR layer. The DBR layer includes a plurality of sloped sidewalls. In some embodiments, the method further includes forming a dielectric layer over the array of LEDs prior to forming the DBR layer.

In some aspects, the techniques described herein relate to a method of forming an optical emitter, the method including forming an array of optical emitter active regions including a first optical emitter active region and at least a first electrode, forming a first distributed Bragg reflector (DBR) between the first optical emitter active region and a circuitry element having a first circuit, electrically connecting the first circuit to the first optical emitter active region through the first electrode, and coupling the first optical emitter active region to the first circuit through a first direct bonding interface.

In some embodiments, the method further includes forming a second DBR over the first optical emitter active region at a light output surface of the optical emitter. In some embodiments, the method further includes hybrid bonding the second DBR to an interposer.

In some embodiments, the method further includes hybrid bonding the first DBR to the circuitry element, where the first direct bonding interface is between the first DBR and the circuitry element.

In some embodiments, the method further includes direct bonding the first DBR to a first LED, where the first LED includes the first optical emitter active region and the first electrode.

In some embodiments, the first electrode includes an optically transparent and electrically conducting material. In some embodiments, the first electrode extends across a surface of a first LED including the first optical emitter active region and the first electrode.

In some embodiments, the circuitry element includes a CMOS driver or a TFT backplane.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the apparatus, methods, and systems described herein may be embodied in a variety of other forms; furthermore, various omissions, substitutions, and changes in the form of the methods and systems described herein may be made without departing from the spirit of the disclosure. Any suitable combination of the elements and acts of the various embodiments described above can be combined to provide further embodiments. The accompanying claims and their equivalents are intended to cover such forms or modifications as would fall within the scope and spirit of the disclosure.

1. An optoelectronic illumination source, comprising:
an array of light emitting devices, including a first device, the first device having a first electrode and second electrode;
a distributed Bragg reflector (DBR) layer comprising a direct bonding surface; and
a circuitry element comprising a first circuit and a plurality of contacts including a first contact electrically coupled to the first electrode and a second contact electrically coupled to the second electrode,
wherein the first device is directly bonded to the first circuit through the direct bonding surface of the DBR layer, and
wherein a continuous portion of the DBR layer covers a majority of a surface of the first device.

2. The optoelectronic illumination source of claim 1, wherein the DBR layer comprises a first surface and a second surface, the second surface opposite the first surface, wherein the first surface is disposed over the first electrode, and wherein the second surface comprises the direct bonding surface.

3. (canceled)

4. (canceled)

5. (canceled)

6. The optoelectronic illumination source of claim 1, wherein the DBR layer comprises a plurality of sidewalls, wherein the DBR layer conforms to the array of light emitting devices.

7. (canceled)

8. (canceled)

9. (canceled)

10. The optoelectronic illumination source of claim 1, wherein at least the first electrode or the second electrode comprises an optically transparent and electrically conducting material.

11. (canceled)

12. The optoelectronic illumination source of claim 1, wherein the DBR layer comprises a plurality of DBR contacts including a first DBR contact, the plurality of DBR contacts coextensive with the DBR layer, wherein the first DBR contact has a width in a range between approximately 0.5 μm and 50 ρm.

13. The optoelectronic illumination source of claim 1, wherein the circuitry element comprises a CMOS driver or a TFT backplane, and the array of light emitting devices comprises an array of microLEDs.

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. A method of forming an optical emitter, the method comprising:
forming an optical emitter active region and at least a first electrode on a substrate;
forming a distributed Bragg reflector (DBR) layer over the optical emitter active region, the DBR layer comprising a first side coupled to the optical emitter active region and a second side opposite the first side;
forming a plurality of first contacts coextensive in thickness with the DBR layer; and
polishing the second side of the DBR layer to form a hybrid bonding layer.

31. The method of claim 30 further comprising depositing the first electrode over the optical emitter active region and a second electrode over the substrate.

32. (canceled)

33. (canceled)

34. (canceled)

35. The method of claim 30, further comprising forming a hybrid bond between the hybrid bonding layer of the DBR layer and a circuitry element.

36. (canceled)

37. (canceled)

38. The method of claim 30, wherein forming the plurality of first contacts comprises etching and filling etched regions in the DBR layer to form individual contacts of the plurality of first contacts, wherein the individual contacts have widths in a range between approximately 0.5 μm and 50 μm.

39. (canceled)

40. (canceled)

41. (canceled)

42. An optoelectronic light emitting device comprising:
a first semiconductor substrate;
a first light emitting device; and
a DBR layer having a first side and a second side opposite the first side, the first side disposed over the first light emitting device, and wherein the DBR layer comprises at least a first contact in electrical communication with an active region of the first light emitting device, wherein at least the first contact is coextensive in thickness with the DBR layer, and wherein the second side of the DBR layer comprises a hybrid bonding surface, the hybrid bonding surface to directly bond the DBR layer to a substrate comprising contacts.

43. The optoelectronic light emitting device of claim 42, further comprising a first electrode between the first light emitting device and the DBR layer, wherein the first electrode is in electrical communication with the first contact, and wherein the first electrode comprises an optically transparent and electrically conducting material.

44. The optoelectronic light emitting device of claim 43, wherein the first electrode extends across a surface of the first light emitting device.

45. The optoelectronic light emitting device of claim 42, wherein the substrate comprising contacts comprises an interposer, a CMOS driver or a TFT backplane.

46. (canceled)

47. The optoelectronic light emitting device of claim 42, further comprising a first dielectric layer disposed over the first semiconductor substrate, wherein the first dielectric layer encapsulates the first light emitting device, a first electrode, and a second electrode.

48. The optoelectronic light emitting device of claim 47, wherein the first side of the DBR layer is disposed over the first dielectric layer.

49. The optoelectronic light emitting device of claim 42, wherein the first light emitting device is a laser diode device.

50. An optoelectronic illumination source comprising the optoelectronic light emitting device of claim 49 and a circuitry element, wherein the DBR layer is hybrid bonded to the circuitry element.

51. The optoelectronic illumination source of claim 50, wherein the circuitry element comprises a waveguide optically coupled to receive light from the laser diode device.

52. The optoelectronic light emitting device of claim 42, wherein the first light emitting device is a microLED.

53. -89. (canceled)
